(19) United States
(12) Patent Application Publication
(10) Pub. No.: US 2011/0240085 A1
(43) Pub. Date: Oct. 6, 2011

(54) DYE-SENSITIZED SOLAR CELL

(75) Inventor: Miho SASAKI, Tokyo-to (JP)

(73) Assignee: DAI NIPPON PRINTING CO., LTD., Tokyo-to (JP)

(21) Appl. No.: 13/049,002

(22) Filed: Mar. 16, 2011

(30) Foreign Application Priority Data
Mar. 30, 2010 (JP) 2010-079160

(51) Int. Cl. H01L 31/042; H01L 31/0224; H01L 51/46

(52) U.S. Cl. 136/244; 136/256

(57) ABSTRACT

A main object of the present invention is to provide a dye-sensitized solar cell capable of improving photoelectric conversion efficiency, which is obtained at low costs, and a dye-sensitized solar cell module using this. To solve the above-mentioned problem, the present invention provides a dye-sensitized solar cell, comprising: an oxide semiconductor electrode substrate having: a first electrode base material provided with a function as an electrode, and a porous layer formed on the first electrode base material and containing a dye-sensitizer-supported fine particle of a metal oxide semiconductor; and a counter substrate having: a second electrode base material provided with a function as an electrode, and a catalyst layer formed on the above-mentioned second electrode base material; an electrolyte layer including a redox pair and formed between the oxide semiconductor electrode substrate and the counter substrate which are disposed such that the porous layer and the catalyst layer are opposed to each other, wherein at least one of the first electrode base material and the second electrode base material is a base material having transparency, and the catalyst layer contains an insulating transparent fine particle and a conductive polymer compound.

### BACKGROUND OF THE INVENTION

1. Field of the Invention

The present invention relates to a high-quality dye-sensitized solar cell with high photoelectric conversion efficiency, which is obtained at low costs.

2. Description of the Related Art

In recent years, an environmental issue such as global warming, resulting from the increase of carbon dioxide, has become so serious that measures thereagainst have been promoted on a worldwide basis. Above all, active research and development on a solar cell utilizing solar light energy have been promoted as a clean energy source with fewer burdens on the environment. A monocrystal silicon solar cell, a polycrystalline silicon solar cell, an amorphous silicon solar cell and a compound semiconductor solar cell have been already put to practical use as such a solar cell, but yet the problem is that these solar cells require high production costs. Thus, a dye-sensitized solar cell has been receiving attentions, researched and developed as a solar cell with fewer environmental burdens, which may decrease production costs.

FIGS. 4A and 4B are each a schematic cross-sectional view showing an example of a general dye-sensitized solar cell. As shown in FIG. 4A, a general dye-sensitized solar cell 100 comprises: an oxide semiconductor electrode substrate 110: having a first electrode base material 111 which has a transparent base material 111b and a transparent electrode layer 111a formed on the transparent base material 111b, and a porous layer 112 formed on the transparent electrode layer 111a, containing a dye-sensitizer-supported fine particle of a metal oxide semiconductor; a counter substrate 120 having: a second electrode base material 121 provided with a function as an electrode, and a catalyst layer 122 formed on the second electrode base material 121; an electrolyte layer 130 formed between the oxide semiconductor electrode substrate 110 and the counter substrate 120 so as to contact with the porous layer 112; and a sealing agent 140 for sealing the dye-sensitized solar cell 100. Then, the dye sensitizer adsorbed onto a surface of the fine particle of a metal oxide semiconductor in the porous layer 112 is excited by receiving solar light from the oxide semiconductor electrode substrate 110 side, and an excited electron is conducted to the transparent electrode layer 111a and conducted to the second electrode base material 121 through an external circuit. Thereafter, the returning of the electron to a ground level of the dye sensitizer through a redox pair causes electric power generation.

FIG. 4A is showing as an example a dye-sensitized solar cell of the so-called ‘sequential structure cell type’, in which the first electrode base material 111 has transparency and solar light is received from the oxide semiconductor electrode substrate 110 side. Further, a dye-sensitized solar cell having a constitution of the so-called ‘inverse structure cell type’, in which the second electrode base material 121 has transparency and solar light is received from the counter substrate 120 side is also known as exemplified in FIG. 4B. In FIG. 4B, the second electrode base material 121 has a transparent base material 121b and a transparent electrode layer 121a formed on the transparent base material 121b, and the first electrode base material 111 does not have transparency.

Although not shown in the drawings, the above-mentioned dye-sensitized solar cell occasionally has a constitution such that both the above-mentioned first electrode base material and second electrode base material are base materials having transparency and solar light may be received from either the above-mentioned oxide semiconductor electrode substrate side or counter substrate side.

Here, the above-mentioned catalyst layer used for the above-mentioned counter substrate functions as a catalyst for reducing an oxidant of a redox pair in the above-mentioned electrolyte layer, and is formed for improving power generation efficiency of the above-mentioned dye-sensitized solar cell. An evaporated platinum film is generally used as such a catalyst layer. However, platinum is expensive and equipment for forming an evaporated film is required, so that the problem is that production costs of the above-mentioned dye-sensitized solar cell rise. Also, the problem is that a catalyst layer made of the above-mentioned evaporated platinum film is insufficient in durability.

Thus, a catalyst layer made of a conductive polymer compound has been discussed as the above-mentioned catalyst layer instead of the evaporated platinum film. However, the problem is that the above-mentioned catalyst layer made of a conductive polymer compound is inferior in catalyst performance as compared with the catalyst layer made of the evaporated platinum film. Thus, the improvement of the above-mentioned catalyst performance has been discussed by adding a conductive material such as carbon fine particle and carbon nanotube to the above-mentioned conductive polymer compound (Japanese Patent Application Publication No. 2008-71605).

However, in the case of adding the above-mentioned conductive material into the catalyst layer, transparency of the above-mentioned catalyst layer deteriorates; therefore, a dye-sensitized solar cell having the above-mentioned catalyst layer may not sufficiently receive solar light, so that the problem is that there is a possibility of deteriorating power generation efficiency.

In a dye-sensitized solar cell, the improvement of utilization efficiency of solar light has been demanded.

### SUMMARY OF THE INVENTION

[Patent Document 1] Japanese Patent Application Publication No. 2008-71605

The main object of the present invention is to provide a dye-sensitized solar cell capable of improving photoelectric conversion efficiency, which is obtained at low costs, and a dye-sensitized solar cell module using this.

To solve the problem, the present invention provides a dye-sensitized solar cell comprising: an oxide semiconductor electrode substrate having: a first electrode base material provided with a function as an electrode, and a porous layer formed on the first electrode base material and containing a dye-sensitizer-supported fine particle of a metal oxide semiconductor; a counter substrate having: a second electrode base material provided with a function as an electrode, and a catalyst layer formed on the second electrode base material; and an electrolyte layer including a redox pair and formed between the oxide semiconductor electrode substrate and the counter substrate which are disposed such that the porous layer and the catalyst layer are opposed to each other, wherein at least one of the first electrode base material and the second electrode base material is a base material having transparency, and wherein the catalyst layer contains an insulating transparent fine particle and a conductive polymer compound.

According to the present invention, the above-mentioned catalyst layer contains an insulating transparent fine particle and a conductive polymer compound, so that irregularities may be formed on the above-mentioned catalyst layer surface and contact area with the above-mentioned electrolyte layer may be enlarged; therefore, a dye-sensitized solar cell with high power generation efficiency is provided. The above-mentioned catalyst layer contains an insulating transparent fine particle, so that the light scattering function of scattering solar light entering a dye-sensitized solar cell or reflected light of the above-mentioned solar light may be provided for the above-mentioned catalyst layer; therefore, utilization efficiency of solar light may be improved and a dye-sensitized solar cell with high photoelectric conversion efficiency is provided. The above-mentioned insulating transparent fine particle is contained in the above-mentioned catalyst layer, so that transparency of the above-mentioned catalyst layer may be improved. Accordingly, in a dye-sensitized solar cell of the present invention, transmittance of incident light and reflected light of solar light into the above-mentioned catalyst layer may be raised, so that a dye-sensitized solar cell with high photoelectric conversion efficiency is also obtained.

In the present invention, the above-mentioned insulating transparent fine particle is preferably made of a transparent resin. Since the above-mentioned insulating transparent fine particle is made of a transparent resin, so that dispersibility of the insulating transparent fine particle into the above-mentioned catalyst layer-forming coating material may be rendered favorable. Accordingly, in forming the above-mentioned catalyst layer, the above-mentioned catalyst layer with the above-mentioned insulating transparent fine particle favorably dispersed in the above-mentioned conductive polymer compound may be easily formed. As compared with the case of using a transparent inorganic material for the insulating transparent fine particle, adhesion properties between the above-mentioned conductive polymer compound and insulating transparent fine particle may be rendered so high that durability of the catalyst layer may be improved.

In the present invention, it is preferable that a refractive index of the above-mentioned insulating transparent fine particle differs from a refractive index of the above-mentioned conductive polymer compound. Thus, so high light scattering function may be provided for the above-mentioned catalyst layer that a dye-sensitized solar cell with high photoelectric conversion efficiency is obtained.

In the present invention, it is preferable that transparency of the above-mentioned insulating transparent fine particle is higher than transparency of the above-mentioned conductive polymer compound. Thus, transparency of the above-mentioned catalyst layer may be improved.

In the present invention, it is preferable that at least the above-mentioned second electrode base material is a base material having transparency. The above-mentioned catalyst layer is so excellent in transparency that transparency of a counter substrate may be rendered high; therefore, solar light may be favorably received from the counter substrate side and a high-quality dye-sensitized solar cell with high photoelectric conversion efficiency is obtained.

The present invention provides a dye-sensitized solar cell module, comprising a dye-sensitized solar cells connected by plurality, wherein each of the dye-sensitized solar cell comprises: an oxide semiconductor electrode substrate having: a first electrode base material provided with a function as an electrode, and a porous layer formed on the first electrode base material and containing a dye-sensitizer-supported fine particle of a metal oxide semiconductor; a counter substrate having a second electrode base material provided with a function as an electrode, and a catalyst layer formed on the second electrode base material; and an electrolyte layer including a redox pair and formed between the oxide semiconductor electrode substrate and the counter substrate which are disposed such that the porous layer and the catalyst layer are opposed to each other, wherein at least one of the first electrode base material and the second electrode base material is a base material having transparency, and the catalyst layer contains an insulating transparent fine particle and a conductive polymer compound.

According to the present invention, the above-mentioned dye-sensitized solar cell allows a high-quality dye-sensitized solar cell module which is obtained at low costs.

### EFFECTS OF THE INVENTION

According to the present invention, the above-mentioned catalyst layer contains the above-mentioned insulating transparent fine particle and conductive polymer compound, so that contact area of the above-mentioned catalyst layer and electrolyte layer may be enlarged; therefore, a dye-sensitized solar cell with high power generation efficiency is obtained. The above-mentioned catalyst layer contains the above-mentioned insulating transparent fine particle, so that the catalyst layer having the light scattering function and high transparency is provided. Therefore, a dye-sensitized solar cell with high photoelectric conversion efficiency is obtained.

### BRIEF DESCRIPTION OF THE DRAWINGS

FIG. 1 is a schematic cross-sectional view showing an example of a dye-sensitized solar cell of the present invention;

FIG. 2 is a schematic cross-sectional view showing another example of a dye-sensitized solar cell of the present invention;

FIG. 3 is a schematic cross-sectional view showing an example of a dye-sensitized solar cell module of the present invention; and

FIGS. 4A and 4B are each a schematic cross-sectional view showing an example of a dye-sensitized solar cell.

### DESCRIPTION OF THE PREFERRED EMBODIMENT

A dye-sensitized solar cell and a dye-sensitized solar cell module of the present invention are hereinafter described in detail.

A. Dye-Sensitized Solar Cell

First, a dye-sensitized solar cell of the present invention is described.

The dye-sensitized solar cell of the present invention comprises: an oxide semiconductor electrode substrate having: a first electrode base material provided with a function as an electrode, and a porous layer formed on the above-mentioned first electrode base material and containing a dye-sensitizer-supported fine particle of a metal oxide semiconductor; a counter substrate having: a second electrode base material provided with a function as an electrode, and a catalyst layer formed on the above-mentioned second electrode base material; and an electrolyte layer including a redox pair and formed between the above-mentioned oxide semiconductor electrode substrate and the above-mentioned counter substrate which are disposed such that the porous layer and the catalyst layer are opposed to each other, wherein at least one of the above-mentioned first electrode base material and the above-mentioned second electrode base material is a base material having transparency, and wherein the catalyst layer contains an insulating transparent fine particle and a conductive polymer compound.

According to the present invention, the above-mentioned catalyst layer contains the above-mentioned insulating transparent fine particle and conductive polymer compound, so that surface area of the above-mentioned catalyst layer may be enlarged and contact area with the above-mentioned electrolyte layer may be enlarged; therefore, a dye-sensitized solar cell with high power generation efficiency is obtained.

Also, according to the present invention, the above-mentioned catalyst layer contains the insulating transparent fine particle, so that the light scattering function maybe provided for the dye-sensitized solar cell of the present invention. Therefore, for example, in the case where the above-mentioned catalyst layer is formed on the second electrode base material made of a base material having transparency, incident light through the second electrode base material may be scattered by the above-mentioned catalyst layer, so that incident light of solar light may be effectively utilized.

On the other hand, in the case where the above-mentioned second electrode base material is made of a metallic foil having no transparency and the like, solar light entering from the above-mentioned first electrode base material side is reflected by the specular effect of the metallic foil. Therefore, for example, in the case where the above-mentioned catalyst layer is formed on the second electrode base material made of the above-mentioned metallic foil and the like, reflected light of the above-mentioned solar light may be scattered by the above-mentioned catalyst layer, so that reflected light of the solar light may be effectively utilized.

Accordingly, in the present invention, the above-mentioned catalyst layer has the light scattering function, so that utilization efficiency of the solar light may be improved.

In addition, according to the present invention, the above-mentioned insulating transparent fine particle is contained in the above-mentioned catalyst layer, so that transparency of the above-mentioned catalyst layer may be improved. Accordingly, in the dye-sensitized solar cell of the present invention, transmittance of incident light and reflected light of solar light into the above-mentioned catalyst layer may be raised, so that a dye-sensitized solar cell with high photoelectric conversion efficiency is also provided.

In the dye-sensitized solar cell of the present invention, the light scattering function of the above-mentioned catalyst layer varies with the presence or absence of transparency of the second electrode base material on which the above-mentioned catalyst layer is formed. The dye-sensitized solar cell of the present invention is each described hereinafter while divided into two embodiments of an embodiment such that the above-mentioned second electrode base material is a base material having transparency (hereinafter regarded as a first embodiment) and an embodiment such that the above-mentioned second electrode base material is a base material having no transparency (hereinafter regarded as a second embodiment).

### 1. Dye-Sensitized Solar Cell of First Embodiment

A dye-sensitized solar cell of the embodiment has a base material having transparency as the second electrode base material.

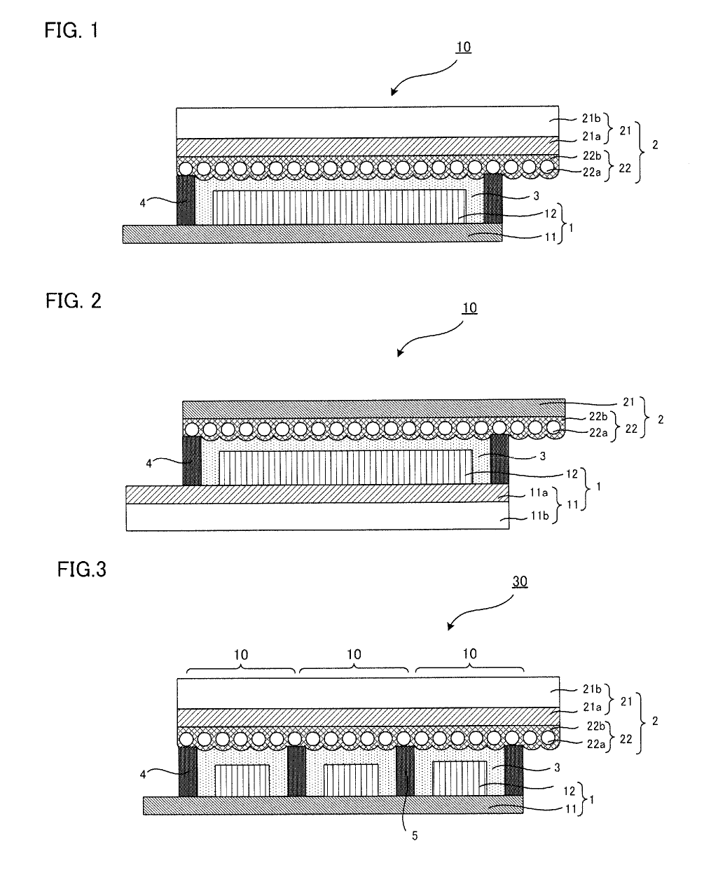

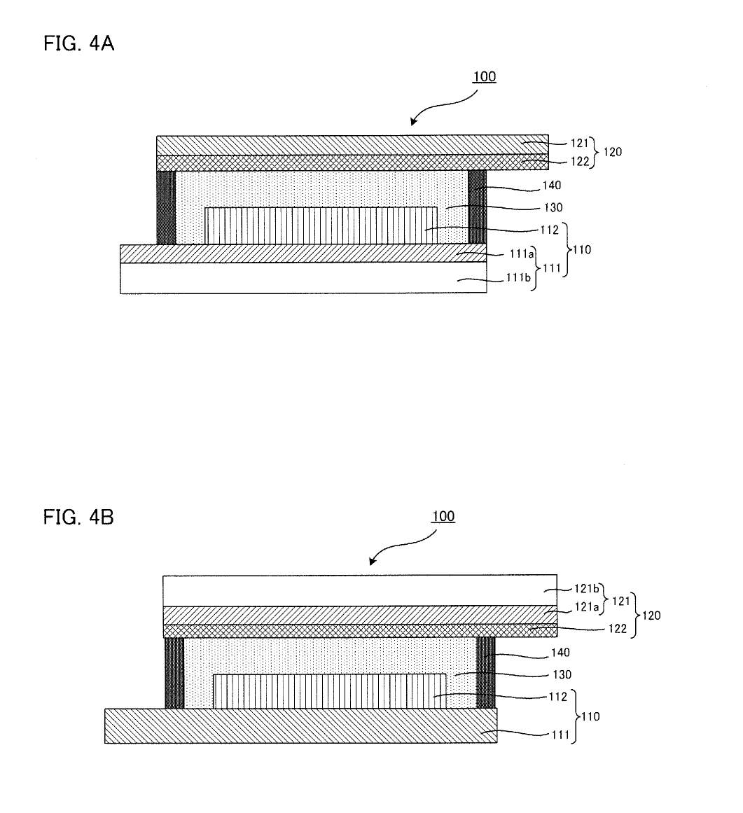

A dye-sensitized solar cell of the present embodiment is described by using a drawing. FIG. 1 is a schematic cross-sectional view showing an example of a dye-sensitized solar cell of the embodiment. As shown in FIG. 1, a dye-sensitized solar cell 10 of the embodiment comprises: an oxide semiconductor electrode substrate 1 having: a first electrode base material 11 made of a metallic foil, and a porous layer 12 formed on the first electrode base material 11 and having a dye-sensitizer-supported fine particle of a metal oxide semiconductor; a counter substrate 2 having: a second electrode base material 21 having a transparent base material 21b and a transparent electrode layer 21a formed on the transparent base material 21b, and a catalyst layer 22 formed on the transparent electrode layer 21a and containing an insulating transparent fine particle 22a and a conductive polymer compound 22b; and an electrolyte layer 3 including a redox pair and formed between the oxide semiconductor electrode substrate 1 and the counter substrate 2 which are disposed such that the porous layer 12 and the catalyst layer 22 are opposed to each other. Also, as shown in FIG. 1, the ends of the dye-sensitized solar cell 10 are sealed generally by a sealing agent 4 or the like.

As described above, in the embodiment, the above-mentioned catalyst layer is formed on the second electrode base material made of a base material having transparency, so that incident light through the above-mentioned second electrode base material may be scattered by the above-mentioned catalyst layer and incident light of solar light may be effectively utilized. Therefore, a dye-sensitized solar cell with high photoelectric conversion efficiency is obtained.

Each member used for a dye-sensitized solar cell of the embodiment is hereinafter described.

(1) Counter Substrate

The counter substrate used for the embodiment has the second electrode base material and the catalyst layer formed on the above-mentioned second electrode base material. The above-mentioned catalyst layer and second electrode base material are each described hereinafter.

(a) Catalyst Layer

The catalyst layer used for the embodiment contains an insulating transparent fine particle and a conductive polymer compound. The above-mentioned insulating transparent fine particle and conductive polymer compound are each described hereinafter.

(i) Insulating Transparent Fine Particle

First, the insulating transparent fine particle used for the above-mentioned catalyst layer is described.

The average particle diameter of the insulating transparent fine particle used for the above-mentioned catalyst layer is not particularly limited if contact area of the above-mentioned catalyst layer and the after-mentioned electrolyte layer may be enlarged; preferably within a range of 1 nm to 100 μm, above all within a range of 100 nm to 30 μm, and particularly within a range of 1 μm to 15 μm. The reason therefor is that in the case where the average particle diameter of the insulating transparent fine particle is less than the above-mentioned range, even though the insulating transparent fine particle is contained in the after-mentioned conductive polymer compound to form the catalyst layer, contact area of the above-mentioned catalyst layer and the after-mentioned electrolyte layer may not sufficiently be enlarged and catalyst performance of the catalyst layer is improved with difficulty. Also, the reason therefor is that in the case where the average particle diameter of the above-mentioned insulating transparent fine particle is more than the above-mentioned range, the above-mentioned catalyst layer is formed with difficulty.

Here, average particle diameter is generally used for denoting granularity of particles, and is a value measured by a laser method in the present embodiment. The laser method is a method such that particles are dispersed into solvent, and scattered light obtained by irradiating the dispersion solvent with a laser beam is thinned and computed to thereby measure average particle diameter and particle size distribution. The above-mentioned average particle diameter is a value measured by using the particle size analyzer MICROTRACK UPA Model-9230™ manufactured by Leeds and Northrup co. uk as a particle size measuring instrument by the laser method.

The shape of the above-mentioned insulating transparent fine particle is not particularly limited if it may be favorably dispersed into the after-mentioned conductive polymer compound; specific examples thereof include a spherical shape and a needle shape.

The transparency of the above-mentioned insulating transparent fine particle is not particularly limited if it is such transparency that may transmit solar light. In the embodiment, transmittance of light with a wavelength of 400 nm to 800 nm is preferably 70% or more, and more preferably 80% or more, above all.

The transparency of the above-mentioned insulating transparent fine particle is preferably higher than the transparency of the after-mentioned conductive polymer compound. Thus, the reason therefor is that entire light transmittance and diffuse light transmittance of the above-mentioned catalyst layer may be improved.

The transparency of the above-mentioned insulating transparent fine particle is a value measured by a measuring method in conformity to JIS K7361-1:1997.

The insulating transparent fine particle used for the embodiment is not particularly limited if it may provide the light scattering function for the above-mentioned catalyst layer. It is preferable that refractive index of the above-mentioned insulating transparent fine particle differs from refractive index of the above-mentioned conductive polymer compound, and that refractive index difference between refractive index of the above-mentioned insulating transparent fine particle and refractive index of the conductive polymer compound becomes larger. The reason therefor is that larger refractive index difference between the two may provide higher light scattering function for the above-mentioned catalyst layer.

The refractive index difference between refractive index of the above-mentioned insulating transparent fine particle and refractive index of the after-mentioned conductive polymer compound is not particularly limited if it is such refractive index difference as may provide the light scattering function for the above-mentioned catalyst layer.

The refractive index of the above-mentioned insulating transparent fine particle is not particularly limited if it differs from refractive index of the after-mentioned conductive polymer compound and may provide sufficient light scattering function for the above-mentioned catalyst layer; preferably within a range of 1.1 to 1.9, above all within a range of 1.3 to 1.7, and particularly within a range of 1.4 to 1.6. The reason therefor is that in the case where refractive index of the insulating transparent fine particle is less than the above-mentioned range, the light scattering function is provided for the above-mentioned catalyst layer with difficulty. Also, the reason therefor is that in the case where refractive index of the insulating transparent fine particle is more than the above-mentioned range, the insulating transparent fine particle is formed with difficulty.

The above-mentioned refractive index is a value obtained by measuring refractive index of the above-mentioned insulating transparent fine particle while using the refractometer KPR-200™ manufactured by KALNEW Co., Ltd., the refractometer PR-2™ manufactured by CARL ZEISS JENA, and the Abbe refractometer NAR-1T SOLID™ manufactured by ATAGO CO., LTD.

The content of the above-mentioned insulating transparent fine particle in a solid component of the above-mentioned catalyst layer is preferably within a range of 0.1% by mass to 99% by mass, above all within a range of 1% by mass to 50% by mass, and particularly within a range of 5% by mass to 35% by mass. The reason therefor is that in the case where the content of the insulating transparent fine particle is less than the above-mentioned range, even though the insulating transparent fine particle is contained in the above-mentioned catalyst layer, surface area of the catalyst layer is enlarged with difficulty to improve catalyst performance, and that in the case where the content of the insulating transparent fine particle is more than the above-mentioned range, the above-mentioned catalyst layer is formed with difficulty.

The insulating transparent fine particle used for the embodiment is not particularly limited if it has transparency and may form the above-mentioned catalyst layer together with the after-mentioned conductive polymer compound, and yet it is preferably made of a transparent resin. The reason therefor is that a transparent resin is so small in specific gravity as compared with a transparent inorganic material that the above-mentioned insulating transparent fine particle is easily dispersed favorably into a catalyst layer-forming coating material in forming the above-mentioned catalyst layer.

Here, in the case of using a transparent inorganic material as the above-mentioned insulating transparent fine particle, adhesion properties between the insulating transparent fine particle as inorganic material and the conductive polymer compound as organic material are so insufficient as to bring a possibility of causing a crack or the like in the above-mentioned catalyst layer. On the other hand, in the case of using transparent resin as the above-mentioned insulating transparent fine particle, the above-mentioned transparent resin and conductive polymer compound are both organic material, so that as compared with the case of using a transparent inorganic material for the above-mentioned insulating transparent fine particle, adhesion properties between the above-mentioned insulating transparent fine particle and conductive polymer compound may be rendered high. Therefore, durability of the above-mentioned catalyst layer may be improved.

Examples of transparent resin used for the above-mentioned insulating transparent fine particle include a polystyrene resin, crosslinked polymethyl methacrylate, a cellulosic resin, a polyester resin, a polyamide resin, a polyacrylic acid ester resin, a polyacrylic resin, a polycarbonate resin, a polyurethane resin, a polyolefin resin, a polyvinyl acetal resin, a fluororesin, a polyimide resin, and polyhydric alcohols such as polyethylene glycol.

(ii) Conductive Polymer Compound

Next, the conductive polymer compound used for the above-mentioned catalyst layer is described.

The conductive polymer compound used for the present embodiment is not particularly limited if it may disperse the above-mentioned insulating transparent fine particle and form the catalyst layer on the after-mentioned second electrode base material, and yet, it preferably has transparency. Since the above-mentioned conductive polymer compound has transparency, transparency of the above-mentioned counter substrate may be further improved. The transparency of the above-mentioned conductive polymer compound is preferably approximately the same as the transparency of the above-mentioned insulating transparent fine particle, but the conductive polymer compound used for a general dye-sensitized solar cell is inferior in transparency to the above-mentioned insulating transparent fine particle. Therefore, the transparency of the above-mentioned conductive polymer compound is preferably such that the catalyst layer containing the above-mentioned insulating transparent fine particle and the above-mentioned conductive polymer compound may exhibit the transparency of the after-mentioned catalyst layer.

Examples of such a conductive polymer compound include polyaniline, polythiophene, polypyrrole and derivatives thereof.

The content of the above-mentioned conductive polymer compound in a solid component of the above-mentioned catalyst layer is not particularly limited if it is such a content as may form the above-mentioned catalyst layer on the after-mentioned second electrode base material; preferably within a range of 0.1% by mass to 99.9% by mass, above all within a range of 10% by mass to 80% by mass, and particularly within a range of 30% by mass to 65% by mass. The reason therefor is that in the case where the content of the conductive polymer compound is less than the above-mentioned range, there is a possibility of forming the catalyst layer on the after-mentioned second electrode base material with difficulty; and that in the case where the content of the conductive polymer compound is more than the above-mentioned range, there is a possibility of being incapable of obtaining the effect in the case of containing the above-mentioned insulating transparent fine particle, that is to say, the effect of enlarging surface area of the catalyst layer, the effect of improving transparency of the catalyst layer, and the effect of being capable of providing light scattering property for the catalyst layer.

(iii) Catalyst Layer

The catalyst layer used for the embodiment has the above-mentioned insulating transparent fine particle and conductive polymer compound.

The thickness of the catalyst layer used for the embodiment is not particularly limited if the catalyst layer may be formed at a certain thickness on the after-mentioned second electrode base material and the thickness is such a thickness as may have catalyst performance; preferably within a range of 10 nm to 100 μm, above all within a range of 1 μm to 50 μm, and particularly within a range of 2 μm to 30 μm. The reason therefor is that in the case where the thickness of the catalyst layer is less than the above-mentioned range, the catalyst layer is formed at a certain thickness on the after-mentioned second electrode base material with difficulty; and that in the case where the thickness of the catalyst layer is more than the above-mentioned range, the dye-sensitized solar cell of the embodiment is thinly formed with such a difficulty that the dye-sensitized solar cell of a thin film in increasing demand in recent years is achieved with difficulty.

The transparency of the above-mentioned catalyst layer is not particularly limited if the dye-sensitized solar cell of the embodiment may be operated by receiving solar light from the above-mentioned counter substrate side; in the embodiment, transmittance of light with a wavelength of 400 nm to 800 nm is preferably 70% or more, and more preferably 80% or more. The reason therefor is that in the case where the transparency of the catalyst layer is less than the above-mentioned range, incident light of solar light may not sufficiently be transmitted, so that a possibility of deteriorating power generation efficiency of the dye-sensitized solar cell of the embodiment is brought.

The light scattering function of the catalyst layer is not particularly limited if scattering of incident light of solar light allows the dye-sensitized solar cell of the embodiment to effectively utilize solar light. With regard to such a catalyst layer, haze value (haze value=(diffuse light transmittance)/(entire light transmittance)×100) is preferably within a range of 2 to 50, above all within a range of 3 to 30, and particularly within a range of 5 to 20. The reason therefor is that in the case where the above-mentioned haze value is less than the above-mentioned range, the catalyst layer does not have a sufficient light scattering function. Also, the reason therefor is that in the case where that the haze value is more than the above-mentioned range, the catalyst layer is formed with difficulty.

The above-mentioned transparency and haze value of the catalyst layer are values measured by a direct-reading haze meter manufactured by Toyo Seiki Seisaku-Sho, Ltd. or a haze meter manufactured by Suga Test Instruments Co., Ltd. while using an integrating sphere.

A forming method for the catalyst layer is not particularly limited if it may form the catalyst layer containing the above-mentioned insulating transparent fine particle and conductive polymer compound. An example thereof is a forming method by preparing a catalyst layer-forming coating solution such that the above-mentioned insulating transparent fine particle and conductive polymer compound are mixed at a predetermined ratio, applying the solution onto the second electrode base material at a predetermined film thickness and drying.

(b) Second Electrode Base Material

The second electrode base material used for the embodiment is a base material having transparency. The transparency of the second electrode base material used for the embodiment is not particularly limited if it transmits solar light so that the dye-sensitized solar cell of the embodiment may operate by receiving solar light from the above-mentioned counter substrate side. As the transparency of the second electrode base material may be the same as the transparency of the above-mentioned catalyst layer, the description is not repeated here.

Specifically, such a second electrode base material has a transparent base material and a second electrode layer formed on the above-mentioned transparent base material, and has as the above-mentioned second electrode layer any one electrode layer of a transparent electrode layer, a mesh electrode layer, and an electrode layer having a transparent electrode layer and a mesh electrode layer.

The above-mentioned transparent base material and second electrode layer are each described hereinafter.

(i) Transparent Base Material

The transparent base material used for the embodiment is not particularly limited if it has such self-supporting properties as may form the after-mentioned second electrode layer and the above-mentioned catalyst layer and be used as the above-mentioned counter substrate. Examples of such a transparent base material include an inorganic transparent base material and a resinous base material. Among them, a resinous base material is preferable by reason of being lightweight, excellent in processability, and capable of decreasing production costs.

Examples of the above-mentioned resinous base material include base materials made of resin such as an ethylene tetrafluoroethylene copolymer film, a biaxially-oriented polyethylene terephthalate film, a polyether sulfone (PES) film, a polyether ether ketone (PEEK) film, a polyether imide (PEI) film, a polyimide (PI) film, a polyethylene naphthalate film (PEN), and polycarbonate (PC). Among them, in the embodiment, a biaxially-oriented polyethylene terephthalate film (PET), a polyethylene naphthalate film (PEN), and a polycarbonate film (PC) are preferably used.

Examples of the above-mentioned inorganic transparent base material include a synthetic quartz base material and a glass substrate.

The thickness of the transparent base material used for the embodiment may be properly selected in accordance with use of the above-mentioned dye-sensitized solar cell. In general, it is preferably within a range of 10 μm to 2000 μm, particularly within a range of 50 μm to 1800 μm, and further within a range of 100 μm to 1500 μm.

The transparent base material used for the embodiment is preferably excellent in heat resistance, weather resistance, and gas barrier properties of water vapor and others. The reason therefor is that if the above-mentioned transparent base material has gas barrier properties, temporal stability of the dye-sensitized solar cell of the embodiment may be rendered high. Above all, in the embodiment, the transparent base material having gas barrier properties, such that oxygen transmission rate is 1 cc/m²/day·atm or less under the conditions of a temperature of 23° C. and a humidity of 90% and water vapor transmission rate is 1 g/m²/day or less under the conditions of a temperature of 37.8° C. and a humidity of 100%, is preferably used. In the embodiment, in order to achieve such gas barrier properties, an optional gas barrier layer may be provided on the above-mentioned transparent base material. The above-mentioned oxygen transmission rate is a value measured by using an oxygen gas transmission rate measuring device (trade name: OX-TRAN 2/20, manufactured by MOCON, Inc.). The above-mentioned water vapor transmission rate is a value measured by using a water vapor transmission rate measuring device (trade name: PERMATRAN-W 3/31, manufactured by MOCON, Inc.).

(ii) Second Electrode Layer

Next, the second electrode layer used for the present embodiment is described. The second electrode layer used for the embodiment is formed on the above-mentioned transparent base material.

Specific examples of the above-mentioned second electrode layer include a transparent electrode layer, a mesh electrode layer, and an electrode layer having a transparent electrode layer and a mesh electrode layer.

Each of them is hereinafter described.

(Transparent Electrode Layer)

A material composing the transparent electrode layer used for the embodiment is not particularly limited if it is a material having transparency and predetermined conductivity, and a conductive polymer compound and a metal oxide may be used therefor.

The above-mentioned metal oxide is not particularly limited if it has predetermined conductivity and transparency. Examples thereof include SnO₂, ITO, ZnO, and a compound such that zinc oxide is added to indiumoxide (IZO). In the embodiment, any of these metal oxides may be appropriately used, and SnO₂ doped with fluorine (hereinafter referred to as FTO) and ITO are preferably used among them. The reason therefor is that FTO and ITO are excellent in both conductivity and transmission properties of solar light.

On the other hand, examples of the above-mentioned conductive polymer compound include polythiophene, polyethylene sulfonic acid (PSS), polyaniline (PA), polypyrrole and polyethylene dioxythiophene (PEDOT). Also, these may be used by mixture of two kinds or more.

The transparent electrode layer used for the embodiment may have a constitution composed of a single layer or a constitution such that plural layers are laminated. Examples of a constitution such that plural layers are laminated include an aspect such that layers composed of materials different in work functions are laminated and an aspect such that layers composed of different metal oxides are laminated.

The thickness of the transparent electrode layer used for the embodiment is not particularly limited if it is within a range of being feasible for desired conductivity in accordance with use of the above-mentioned dye-sensitized solar cell. Above all, the thickness of the transparent electrode layer in the embodiment is preferably, in general, within a range of 5 nm to 2000 nm, particularly within a range of 10 nm to 1000 nm. The reason therefor is that in the case where the thickness is larger than the above-mentioned range, a homogeneous transparent electrode layer is occasionally formed with difficulty and entire light transmittance is occasionally decreased to obtain a favorable photoelectric conversion efficiency with difficulty; and that in the case where the thickness is smaller than the above-mentioned range, there is a possibility that conductivity of the transparent electrode layer runs short.

The above-mentioned thickness signifies the total thickness obtained by summing up the thickness of all layers in the case where the transparent electrode layer is composed of plural layers.

A method for forming the above-mentioned transparent electrode layer on the transparent base material may be the same as a forming method for a general transparent electrode layer; therefore, the description is not repeated here.

(Mesh Electrode Layer)

Next, the mesh electrode layer is described. The mesh electrode layer used for the embodiment is an electrode layer formed into a mesh by using a conductive material. The above-mentioned mesh electrode layer is formed on the transparent base material and used as a base material having transparency.

Examples of a shape of the mesh electrode layer include a triangular lattice, a parallelogram lattice and a hexagonal lattice.

The film thickness of the mesh electrode layer is not particularly limited if it may have a function as an electrode layer; preferably, within a range of 0.01 μm to 10 μm. The reason therefor is that in the case where the film thickness of the mesh electrode layer is more than the above-mentioned range, material and time for forming the mesh electrode layer are increased so much that production efficiency is decreased and production costs are increased. Also, the reason therefor is that in the case where the film thickness of the mesh electrode layer is less than the above-mentioned range, there is a possibility that the mesh electrode layer does not sufficiently serve a function as an electrode layer.

The ratio of an opening of the mesh electrode layer used for the embodiment is preferably within a range of 50% to 99.9%, above all within a range of 40% to 98%, and particularly within a range of 70% to 95%. The reason therefor is that in the case where the ratio of an opening of the mesh electrode layer is less than the above-mentioned range, the dye-sensitized solar cell of the embodiment may not sufficiently receive solar light from the second electrode base material side, so that there is a possibility of deteriorating power generation efficiency. Also, the reason therefor is that in the case where the ratio of an opening of the mesh electrode layer is more than the above-mentioned range, there is a possibility that the mesh electrode layer does not sufficiently serve a function as an electrode layer.

The line width of the mesh electrode layer and the opening width of the mesh electrode layer are not particularly limited if the above-mentioned second electrode base material may have a function as an electrode layer, but are properly selected in accordance with a shape of the dye-sensitized solar cell to be used. The line width of the mesh electrode layer is preferably within a range of 0.02 μm to 10 mm, above all within a range of 1 μm to 2 mm and particularly within a range of 10 μm to 1 mm. The opening width of the mesh electrode layer is preferably within a range of 1 μm to 2000 μm, above all within a range of 10 μm to 1000 μm and particularly within a range of 100 μm to 500 μm.

The material for the above-mentioned mesh electrode layer is not particularly limited if it is a material having conductivity. Specific examples of the material include copper, aluminum, titanium, chromium, tungsten, molybdenum, platinum, tantalum, niobium, zirconium, zinc, various kinds of stainless steel, and alloy thereof; preferably, titanium, chromium, tungsten, various kinds of stainless steel, and alloy thereof are desirable.

(Electrode Layer Having Transparent Electrode Layer and Mesh Electrode Layer)

An electrode layer having the above-mentioned transparent electrode layer and mesh electrode layer may be used as the second electrode layer used for the embodiment. The above-mentioned constitution allows conductivity to be supplemented by the mesh electrode layer in the case where conductivity of the transparent electrode layer runs short, so that there is the advantage that the dye-sensitized solar cell of the embodiment may be made more excellent in power generation efficiency.

The transparent electrode layer and the mesh electrode layer are the same as were described above; therefore, the description is not repeated here.

(2) Oxide Semiconductor Electrode Substrate

Next, an oxide semiconductor electrode substrate used for the embodiment is described.

The oxide semiconductor electrode substrate used for the embodiment has a first electrode base material provided with a function as an electrode and a porous layer formed on the first electrode base material. The above-mentioned first electrode base material and porous layer used for the embodiment are each described hereinafter.

(a) First Electrode Base Material

The first electrode base material used for the embodiment is not particularly limited if it is provided with a function as an electrode and has such self-supporting properties as may form the after-mentioned porous layer to be used as the oxide semiconductor electrode substrate. It may be a base material having transparency or a base material having no transparency.

In the case where the first electrode base material is a base material having transparency, the base material having transparency, which was described in the above-mentioned section of the second electrode base material, may be used; therefore, the description is not repeated here.

In the case where the first electrode base material of the embodiment is a base material having no transparency, abase material having at least a metal layer may be used as the above-mentioned first electrode base material.

Such a first electrode base material may have at least a metal layer, and may be such that the above-mentioned metal layer is a metallic foil and the above-mentioned first electrode base material is composed of the metallic foil, or such that the above-mentioned first electrode base material has a base material and a metal layer. In the embodiment, among them, the above-mentioned first electrode base material is preferably composed of the metallic foil. The reason therefor is that the above-mentioned first electrode base material is easily prepared.

Specific examples of the metallic foil used for the embodiment include a metallic foil made of copper, aluminum, titanium, chromium, tungsten, molybdenum, platinum, tantalum, niobium, zirconium, zinc, various kinds of stainless steel, and alloy thereof; preferably, a metallic foil made of titanium, chromium, tungsten, various kinds of stainless steel, and alloy thereof is desirable.

The thickness of the metallic foil is not particularly limited if it is within a range of allowing such self-supporting properties as may form the after-mentioned porous layer on the above-mentioned metallic foil; In general, preferably within a range of 5 μm to 1000 μm, more preferably within a range of 10 μm to 500 μm, and even more preferably within a range of 20 μm to 200 μm.

(b) Porous Layer

Next, a porous layer used for the embodiment is described. The porous layer used for the embodiment contains a dye-sensitizer-supported fine particle of a metal oxide semiconductor on a surface thereof, formed on the above-mentioned first electrode base material, and contacts with the after-mentioned electrolyte layer. In the case where the above-mentioned first electrode base material is a base material having transparency, the porous layer is formed on an electrode layer such as a transparent electrode layer of the first electrode base material.

(i) Fine Particle of Metal Oxide Semiconductor

A fine particle of a metal oxide semiconductor used for the embodiment is not particularly limited if it is composed of a metal oxide provided with semiconductor characteristics. Examples of the metal oxide composing the fine particle of a metal oxide semiconductor used for the embodiment include TiO₂, ZnO, SnO₂, ITO, ZrO₂, MgO, Al₂O₃, CeO₂, Bi₂O₃, Mn₃O₄, Y₂O₃, WO₃, Ta₂O₅, Nb₂O₅ and La₂O₃. These fine particles of a metal oxide semiconductor are appropriately used for the embodiment by reason of being so appropriate for forming the porous layer with porous properties that the improvement of energy conversion efficiency and the decrease of costs may be intended.

Among them, in the embodiment, the fine particle of a metal oxide semiconductor composed of TiO₂ is used most preferably. The reason therefor is that TiO₂ is particularly excellent in semiconductor characteristics.

The average particle diameter of the fine particle of a metal oxide semiconductor used for the embodiment is not particularly limited if it allows specific surface area of the porous layer to be within a desired range. In general, preferably within a range of 1 nm to 10 μm and particularly within a range of 10 nm to 1000 nm. The reason therefor is that in the case where the average particle diameter is less than the above-mentioned range, each fine particle of a metal oxide semiconductor is occasionally aggregated to form a secondary particle, and in the case where the average particle diameter is more than the above-mentioned range, there is a possibility that the porous layer is not merely made into a thick film but also porosity of the porous layer, namely, specific surface area is decreased. Here, for example, when specific surface area of the porous layer is decreased, a dye sensitizer sufficient for photoelectric conversion is occasionally supported on the porous layer with difficult.

The average particle diameter of the above-mentioned fine particle of a metal oxide semiconductor signifies a primary particle diameter.

(ii) Dye Sensitizer

A dye sensitizer used for the embodiment is not particularly limited if it may absorb light to cause electromotive force. Examples of such dye sensitizer include organic coloring matter or metal complex coloring matter. Examples of the organic coloring matter include coloring matter such as acridine, azo, indigo, chinone, coumarin, melocyanine, phenylxanthene, indoline and carbazole. In the embodiment, among these organic coloring matter, coumarin coloring matter is preferably used. Also, ruthenium coloring matter is preferably used as the metal complex coloring matter, and ruthenium bipyridine coloring matter and ruthenium terpyridine coloring matter as a ruthenium complex are used particularly preferably. The reason therefor is that such a ruthenium complex is so wide in a wavelength range of light to be absorbed that a wavelength range of light to be subject to photoelectric conversion may be vastly widened.

(iii) Optional Components

Optional components other than the above-mentioned fine particle of a metal oxide semiconductor may be contained in the porous layer used for the embodiment. Examples of the optional components used for the embodiment include a resin. The reason therefor is that, when a resin is contained in the above-mentioned porous layer, brittleness of the porous layer used for the embodiment may be improved.

Examples of such resin include polyvinyl pyrrolidone, ethyl cellulose and caprolactam.

(iv) Others

The thickness of the porous layer used for the embodiment is in general, preferably within a range of 1 μm to 100 μm and particularly within a range of 3 μm to 30 μm.

(3) Electrolyte Layer

Next, an electrolyte layer used for the embodiment is described. The electrolyte layer in the embodiment includes a redox pair.

A redox pair used for the electrolyte layer in the embodiment is not particularly limited if it is generally used for an electrolyte layer of a dye-sensitized solar cell. Above all, a redox pair used for the embodiment is preferably a combination of iodine and iodide and a combination of bromine and bromide.

Examples of a combination of iodine and iodide used as the redox pair for the embodiment include a combination of metal iodide such as LiI, NaI, KI and CaI₂ and I₂.

In addition, examples of the combination of bromine and bromide include a combination of metal bromide such as LiBr, NaBr, KBr and CaBr₂ and Br₂.

The electrolyte layer in the embodiment may contain addition agents such as a crosslinking agent, a photo polymerization initiator, a viscosity bodying agent and a room temperature fused salt as other compounds other than the above-mentioned redox pair.

The electrolyte layer may be an electrolyte layer in any shape of gel, solid and liquid.

(4) Other Members

The dye-sensitized solar cell of the embodiment is not particularly limited if it has the above-mentioned counter substrate, oxide semiconductor electrode substrate and electrolyte layer, but necessary members may be properly added. Examples of such members include a sealing agent for sealing the ends of the above-mentioned dye-sensitized solar cell. The above-mentioned sealing agent may be the same as a sealing agent used for a general dye-sensitized solar cell; therefore, the description is not repeated here.

### 2. Dye-Sensitized Solar Cell of Second Embodiment

A dye-sensitized solar cell of the embodiment has a base material having no transparency as the above-mentioned second electrode base material.

A dye-sensitized solar cell of the embodiment is described by using a drawing. FIG. 2 is a schematic cross-sectional view showing an example of a dye-sensitized solar cell of the embodiment. As shown in FIG. 2, a dye-sensitized solar cell 10 of the embodiment comprises: an oxide semiconductor electrode substrate 1 having: a first electrode base material 11 having a transparent base material 11b and a transparent electrode layer 11a formed on the transparent base material 11b, and a porous layer 12 formed on the transparent electrode layer 11a and containing a dye-sensitizer-supported fine particle of a metal oxide semiconductor; a counter substrate 2 having: a second electrode base material 21 made of a metallic foil, and a catalyst layer 22 formed on the second electrode base material 21 and containing an insulating transparent fine particle 22a and a conductive polymer compound 22b; and an electrolyte layer 3 including a redox pair and formed between the oxide semiconductor electrode substrate 1 and the counter substrate 2 which are disposed such that the porous layer 12 and the catalyst layer 22 are opposed to each other. Also, as shown in FIG. 2, the ends of the dye-sensitized solar cell 10 are generally sealed by a sealing agent 4.

As described above, in the case where the above-mentioned second electrode base material is made of a metallic foil having no transparency, solar light entering from the above-mentioned first electrode base material side is reflected by the specular effect of the metallic foil. Therefore, according to the embodiment, reflected light of the solar light maybe scattered by the above-mentioned catalyst layer, so that reflected light of the solar light may be effectively utilized. Therefore, a dye-sensitized solar cell with high photoelectric conversion efficiency is obtained.

Each member used for a dye-sensitized solar cell of the embodiment is hereinafter described. An electrolyte layer and other members used for the embodiment may be the same as were described in the above-mentioned section of ‘1. Dye-sensitized solar cell of first embodiment’; therefore, the description is not repeated here.

(1) Counter Substrate

The counter substrate used for the embodiment has the second electrode base material and the catalyst layer formed on the above-mentioned second electrode base material. The second electrode base material is a base material having no transparency.

A base material having no transparency used for the above-mentioned second electrode base material may be the same as the first electrode base material having no transparency, which was described in the section of ‘1. Dye-sensitized solar cell of first embodiment’; therefore, the description is not repeated here.

The catalyst layer used for the embodiment contains an insulating transparent fine particle and a conductive polymer compound, and is not particularly limited if it may enlarge contact area of the above-mentioned catalyst layer and electrolyte layer, has transparency, and has the light scattering function of being capable of scattering reflected light of solar light from the second electrode base material. Such a catalyst layer, specifically, may be the same as the catalyst layer described in the above-mentioned section of ‘1. Dye-sensitized solar cell of first embodiment’; therefore, the description is not repeated here.

(2) Oxide Semiconductor Electrode Substrate

The oxide semiconductor electrode substrate used for the embodiment has the above-mentioned first electrode base material and a porous layer formed on the first electrode base material. In the embodiment, the above-mentioned second electrode base material is a base material having no transparency, so that a base material having transparency is used as the first electrode base material.

The first electrode base material in the embodiment may be the same as the second electrode base material described in the above-mentioned section of ‘1. Dye-sensitized solar cell of first embodiment’; therefore, the description is not repeated here. Also, the porous layer may be the same as was described in the above-mentioned section of ‘1. Dye-sensitized solar cell of first embodiment’; therefore, the description is not repeated here.

### 3. Dye-Sensitized Solar Cell

In the present invention, among the dye-sensitized solar cells of above-mentioned each embodiment, the dye-sensitized solar cell of the above-mentioned first embodiment is preferable. In the present invention, the reason therefor is that the above-mentioned catalyst layer is so excellent in transparency that solar light may be favorably received from the counter substrate side.

A method for producing the dye-sensitized solar cell of the present invention may be the same as a method for producing a general dye-sensitized solar cell, and the dye-sensitized solar cell thereof may be produced by the following producing method, for example.

Examples thereof include a producing method such that the counter substrate on which the catalyst layer of the present invention is formed and the above-mentioned oxide semiconductor electrode substrate are disposed such that the porous layer and the catalyst layer are opposed to each other and sealed by a sealing agent, and subsequently an electrolyte layer is formed by injecting a liquid or gel electrolyte between the oxide semiconductor electrode substrate and the counter substrate to thereby produce a dye-sensitized solar cell.

Also, other examples is a producing method such that a polymer electrolyte layer is formed by applying and drying a solid electrolyte layer material on the porous layer of the above-mentioned oxide semiconductor electrode substrate, and subsequently the above-mentioned oxide semiconductor electrode substrate and the counter substrate are contacted and disposed such that the above-mentioned polymer electrolyte layer and the catalyst layer are opposed to each other, and thereby produce a dye-sensitized solar cell.

Both above-mentioned methods for producing a dye-sensitized solar cell are examples, and other general methods for producing a general dye-sensitized solar cell may be used in the present invention.

B. Dye-Sensitized Solar Cell Module

Next, a dye-sensitized solar cell module of the present invention is described.

A dye-sensitized solar cell module of the present invention comprises the dye-sensitized solar cells described in the above-mentioned section of ‘A. Dye-sensitized solar cell’ connected by plurality.

A dye-sensitized solar cell module of the present invention is described by using a drawing.

FIG. 3 is a schematic cross-sectional view showing an example of a dye-sensitized solar cell module of the present invention. As shown in FIG. 3, a dye-sensitized solar cell module 30 of the present invention comprises dye-sensitized solar cells 10 connected by plurality, wherein each of the dye-sensitized solar cell 10 comprises: an oxide semiconductor electrode substrate 1 having: a first electrode base material 11 made of a metallic foil, and a porous layer 12 formed on the first electrode base material 11 and having a dye-sensitizer-supported fine particle of a metal oxide semiconductor; a counter substrate 2 having: a second electrode base material 21 having a transparent base material 21b and a transparent electrode layer 21a formed on the transparent base material 21b, and a catalyst layer 22 formed on the transparent electrode layer 21a and containing an insulating transparent fine particle 22a and a conductive polymer compound 22b; and an electrolyte layer 3 including a redox pair and formed between the oxide semiconductor electrode substrate 1 and the counter substrate 2 which are disposed so that the porous layer 12 and the catalyst layer 22 are opposed to each other. Also, as shown in FIG. 3, the ends of the dye-sensitized solar cell module 30 are generally sealed by a sealing agent 4, and a partition wall 5 is formed in each gap between the dye-sensitized solar cells 10.

The present invention may provide a high-quality dye-sensitized solar cell module with high photoelectric conversion efficiency, which is obtained at low costs, by having the above-mentioned dye-sensitized solar cell.

The dye-sensitized solar cell used for the present invention may be the same as was described in the section of ‘A. Dye-sensitized solar cell’; therefore, the description is not repeated here.

The sealing agent for sealing the ends of the dye-sensitized solar cell module and the partition wall formed in each gap between the dye-sensitized solar cells may be the same as are used for a general dye-sensitized solar cell module; therefore, the description is omitted here.

In the present invention, an aspect such that plural dye-sensitized solar cells are connected is not particularly limited if desired electromotive force may be obtained by the dye-sensitized solar cell module of the present invention. Such an aspect may be an aspect such that the individual dye-sensitized solar cells are connected in series or connected in parallel.

The present invention is not limited to the above-mentioned embodiments. The above-mentioned embodiments are exemplification, and any case is included in the technical scope of the present invention if it has substantially the same constitution as the technical idea described in the claim of the present invention and offers similar operation and effect thereto.

### EXAMPLES

The present invention is hereinafter described more specifically by using examples.

### Example 1

(Production of Oxide Semiconductor Electrode Substrate)

Paste such that 0.5%-ethyl cellulose STD-100™ (manufactured by Nisshin Kasei Kogyo Co., Ltd.) was mixed into titanium oxide particles P25™ (manufactured by Nippon Aerosil Co., Ltd.) in ethanol was applied and dried on a Ti foil with a thickness of 50 μm (manufactured by Etakeuchi Co., Ltd.) as a first electrode base material, and sintered at a temperature of 500° C. for 30 minutes to obtain a porous layer-forming layer with a film thickness of 5 μm. Thereafter, a dye sensitizer solution such that N719 dye (Dyesol) was dissolved by 0.3 mM in acetonitrile/tert-butanol=1/1 solution was prepared, and the above-mentioned Ti foil substrate was immersed in this dye sensitizer solution for 20 hours and thereafter dried to obtain an oxide semiconductor electrode substrate.

(Production of Counter Substrate)

An ITO film/PEN substrate with a film thickness of 125 μm was used as a second electrode base material, and PEDOTPSS (POLY(3,4-ETHYLENEDIOXYTHIOPHENE)POLY(STYRENESULFONATE)) 2% aqueous dispersion (conductive polymer compound) and polystyrene particles Techpolymer™ with an average particle diameter of 8 μm (manufactured by Sekisui Plastics Co., Ltd.) (insulating transparent fine particle) were added on the ITO films that the solid ratio became 2:1, applied to the ITO film/PEN substrate so that the coating amount became 0.3 g/m² (solid ratio), and dried at a temperature of 120° C. for 10 minutes to form a catalyst layer and then obtain a counter substrate.

(Production of Electrolyte Layer and Production of Dye-Sensitized Solar Cell)

An electrolytic solution such that 6-mol/l hexyl metyl imidazolum iodide (manufactured by Tomiyama Pure Chemical Industries, Ltd.), 6-mol/l I₂ (manufactured by Merck Ltd.) and 0.45-mol/l n-metylbenzomidazol (manufactured by Sigma-Aldrich Corporation) were dissolved in hexyl metyl imidazolum tetracyanoborat (manufactured by Merck Ltd.) was prepared. Next, a resin solution such that STD-100™ (manufactured by Nissin Kasei Kogyo Co., Ltd.) was dissolved by 10 w % in ethanol was prepared to produce a resin electrolytic solution such as to mix at the above-mentioned electrolytic solution: resin solution=1:6 (weight ratio).

The resin electrolytic solution was applied on the above-mentioned oxide semiconductor electrode substrate by a solid film thickness of 5 μm, and dried in an oven at a temperature of 100° C. for 5 minutes to obtain a polymer electrolyte layer.

Thereafter, the catalyst layer face of the counter substrate and the polymer electrolyte layer face of the above-mentioned oxide semiconductor electrode substrate were stuck together and thermally laminated by a vacuum laminator to thereby obtain a dye-sensitized solar cell.

### Example 2

A dye-sensitized solar cell was produced similarly to Example 1 except for forming the counter substrate in the following manner.

(Production of Counter Substrate)

An ITO film/PEN substrate with a film thickness of 125 μm was used as a second electrode base material, and PEDOTPSS (POLY(3,4-ETHYLENEDIOXYTHIOPHENE)POLY(STYRENESULFONATE)) 2% aqueous dispersion (conductive polymer compound) and crosslinked polymethyl methacrylate particles Techpolymer™ with an average particle diameter of 2.5 μm (manufactured by Sekisui Plastics Co., Ltd.) (insulating transparent fine particle) were added on the ITO film so that the solid ratio became 2:1, applied to the ITO film/PEN substrate so that the coating amount became 0.3 g/m² (solid ratio), and dried at a temperature of 120° C. for 10 minutes to thereby form a catalyst layer and then obtain a counter substrate.

### Comparative Example 1

A dye-sensitized solar cell was produced similarly to Example 1 except for forming the counter substrate in the following manner.

(Production of Counter Substrate)

An ITO film/PEN substrate with a film thickness of 125 μm was used as a second electrode base material, and PEDOTPSS (POLY(3,4-ETHYLENEDIOXYTHIOPHENE)POLY(STYRENESULFONATE)) 2% aqueous dispersion and carbon fine particles were added on the above-mentioned ITO film so that the solid ratio became 2:1, applied to the ITO film/PEN substrate so that the coating amount became 0.3 g/m² (solid ratio), and dried at a temperature of 120° C. for 10 minutes to thereby form a catalyst layer and then obtain a counter substrate.

### Comparative Example 2

A dye-sensitized solar cell was produced similarly to Example 1 except for forming the counter substrate in the following manner.

(Production of Counter Substrate)

An ITO film/PEN substrate with a film thickness of 125 μm was used as a second electrode base material, and platinum was laminated on the above-mentioned ITO film so as to be an entire light transmittance of 65% to forma catalyst layer and then obtain a counter substrate.

### Comparative Example 3

A dye-sensitized solar cell was produced similarly to Example 1 except for forming the counter substrate in the following manner.

(Production of Counter Substrate)

An ITO film/PEN substrate with a film thickness of 125 μm was used as a second electrode base material, and PEDOTPSS (POLY(3,4-ETHYLENEDIOXYTHIOPHENE)POLY(STYRENESULFONATE)) 2% aqueous dispersion was applied on the above-mentioned ITO film so that the coating amount became 0.3 g/m² (solid ratio), and dried at a temperature of 120° C. for 10 minutes to thereby form a catalyst layer and then obtain a counter substrate.

[Evaluations]

The entire light transmittances (transmittance) of the counter substrates produced in Examples 1 and 2 and Comparative Examples 1 to 3 were measured. The transmittance was measured by using a haze meter (manufactured by Suga Test Instruments Co., Ltd). The results are shown in Table 1. The transmittance shown in Table 1 includes the transmittance of the substrate.

The results of evaluating the performance of the dye-sensitized solar cells obtained in Examples 1 and 2 and Comparative Examples 1 to 3 are shown in Table 1. The performance evaluation of the dye-sensitized solar cell was performed in such a manner that IV characteristics were measured by using a spectral sensitivity forcing device CEP-2000™ (manufactured by Bunkoukeiki Co., Ltd.) to calculate conversion efficiency.

The haze value was measured as the evaluation of the light scattering function of the counter substrates produced in Examples 1 and 2 and Comparative Examples 1 to 3. The haze value was measured by using a haze meter (manufactured by Suga Test Instruments Co., Ltd) used for measuring the entire light transmittance. The results are shown in Table 1.

TABLE 1

| | Transmittance | Conversion | Haze value |
|---|---|---|---|
| | (%) | efficiency (%) | (%) |
| Example 1 | 86 | 2.07 | 14.6 |
| Example 2 | 83 | 2.00 | 10.7 |
| Comparative Example 1 | 63 | 1.64 | 6.5 |
| Comparative Example 2 | 65 | 2.50 | 1.7 |
| Comparative Example 3 | 79 | 1.90 | 0.8 |

In Examples 1 and 2, photoelectric conversion efficiency may be rendered high as compared with Comparative Example 1, in which the catalyst layer containing a conductive polymer compound and carbon fine particles was used, and Comparative Example 3, in which the catalyst layer composed of only a conductive polymer compound was used. The inclusion of an insulating transparent fine particle in the catalyst layer allows transparency of the catalyst layer to be improved and further allows the light scattering function to be provided.

What is claimed is:

1. A dye-sensitized solar cell, comprising:
an oxide semiconductor electrode substrate having: a first electrode base material provided with a function as an electrode, and a porous layer formed on the first electrode base material and containing a dye-sensitizer-supported fine particle of a metal oxide semiconductor;
a counter substrate having: a second electrode base material provided with a function as an electrode, and a catalyst layer formed on the second electrode base material; and
an electrolyte layer including a redox pair and formed between the oxide semiconductor electrode substrate and the counter substrate which are disposed such that the porous layer and the catalyst layer are opposed to each other,
wherein at least one of the first electrode base material and the second electrode base material is a base material having transparency, and
wherein the catalyst layer contains an insulating transparent fine particle and a conductive polymer compound.

2. The dye-sensitized solar cell according to claim 1,
wherein the insulating transparent fine particle is made of a transparent resin.

3. The dye-sensitized solar cell according to claim 1, wherein a refractive index of the insulating transparent fine particle differs from a refractive index of the conductive polymer compound.

4. The dye-sensitized solar cell according to claim 2, wherein a refractive index of the insulating transparent fine particle differs from a refractive index of the conductive polymer compound.

5. The dye-sensitized solar cell according to claim 1, wherein transparency of the insulating transparent fine particle is higher than transparency of the conductive polymer compound.

6. The dye-sensitized solar cell according to claim 2, wherein transparency of the insulating transparent fine particle is higher than transparency of the conductive polymer compound.

7. The dye-sensitized solar cell according to claim 3, wherein transparency of the insulating transparent fine particle is higher than transparency of the conductive polymer compound.

8. The dye-sensitized solar cell according to claim 4, wherein transparency of the insulating transparent fine particle is higher than transparency of the conductive polymer compound.

9. The dye-sensitized solar cell according to claim 1, wherein at least the second electrode base material is the base material having transparency.

10. The dye-sensitized solar cell according to claim 2, wherein at least the second electrode base material is the base material having transparency.

11. The dye-sensitized solar cell according to claim 3, wherein at least the second electrode base material is the base material having transparency.

12. The dye-sensitized solar cell according to claim 4, wherein at least the second electrode base material is the base material having transparency.

13. The dye-sensitized solar cell according to claim 5, wherein at least the second electrode base material is the base material having transparency.

14. The dye-sensitized solar cell according to claim 6, wherein at least the second electrode base material is the base material having transparency.

15. The dye-sensitized solar cell according to claim 7, wherein at least the second electrode base material is the base material having transparency.

16. The dye-sensitized solar cell according to claim 8, wherein at least the second electrode base material is the base material having transparency.

17. A dye-sensitized solar cell module, comprising dye-sensitized solar cells connected by plurality, wherein each of the dye-sensitized solar cells comprises:
an oxide semiconductor electrode substrate having: a first electrode base material provided with a function as an electrode, and a porous layer formed on the first electrode base material and containing a dye-sensitizer-supported fine particle of a metal oxide semiconductor; and
a counter substrate having a second electrode base material provided with a function as an electrode, and a catalyst layer formed on the second electrode base material; and
an electrolyte layer including a redox pair and formed between the oxide semiconductor electrode substrate and the counter substrate which are disposed such that the porous layer and the catalyst layer are opposed to each other,
wherein at least one of the first electrode base material and the second electrode base material is a base material having transparency, and the catalyst layer contains an insulating transparent fine particle and a conductive polymer compound.
